(19) United States
(12) Patent Application Publication
(10) Pub. No.: US 2024/0404924 A1
(43) Pub. Date: Dec. 5, 2024

(54) SEMICONDUCTOR PACKAGE AND FABRICATION METHOD THEREOF

(71) Applicant: MEDIATEK INC., Hsin-Chu (TW)

(72) Inventors: Tsung-Ming Chen, Hsinchu City (TW); Yu-Ting Chou, San Jose, CA (US); Keng-Chang Liang, Hsinchu City (TW); Chiyuan Lu, San Jose, CA (US); Jing-Hong Conan Zhan, Hsinchu City (TW)

(73) Assignee: MEDIATEK INC., Hsin-Chu (TW)

(21) Appl. No.: 18/732,584

(22) Filed: Jun. 3, 2024

Related U.S. Application Data
(60) Provisional application No. 63/506,194, filed on Jun. 5, 2023.

(51) Int. Cl. H01L 23/495; H01L 21/56; H01L 23/00; H01L 23/31; H01L 23/48

(52) U.S. Cl. CPC H01L 23/49513; H01L 21/565; H01L 23/3135; H01L 23/481; H01L 24/29; H01L 24/32; H01L 24/45; H01L 24/48; H01L 24/73; H01L 2224/29139; H01L 2224/32245; H01L 2224/45144; H01L 2224/45147; H01L 2224/48245; H01L 2224/73265; H01L 2924/141

(57) ABSTRACT

A semiconductor package includes a leadframe having a die pad and lead terminals along a perimeter of the die pad, and an IC die mounted on the die pad. The IC die includes I/O pads disposed on an active front surface of the IC die. The IC die includes a semiconductor substrate, a circuit block fabricated on the semiconductor substrate, and a through substrate via (TSV) extending through a thickness of the semiconductor substrate. Bond wires extend between the I/O pads and the lead terminals, respectively. A molding compound encapsulates the IC die, the bond wires, and the leadframe.

### CROSS REFERENCE TO RELATED APPLICATIONS

This application claims the benefit of U.S. Provisional Application No. 63/506,194, filed on Jun. 5, 2023. The content of the application is incorporated herein by reference.

### BACKGROUND

The present disclosure relates generally to the field of chip packaging and, more particularly, to a quad flat non-leaded (QFN) semiconductor package.

The handheld consumer market is aggressive in the miniaturization of electronic products. Driven primarily by the cellular phone and digital assistant markets, manufacturers of these devices are challenged by ever shrinking formats and the demand for more PC-like functionality. Additional functionality can only be achieved with higher performing logic IC's accompanied by increased memory capability. This challenge, combined together in a smaller PC board format, asserts pressure on surface mount component manufactures to design their products to command the smallest area possible.

Many of the components used extensively in today's handheld market have been migrated from traditional leaded frame designs to non-leaded formats. The primary driver for handheld manufacturers is the saved PC board space created by these components' smaller mounting areas. In addition, most components also have reductions in weight and height, as well as an improved electrical performance. As critical chip scale packages are converted to non-leaded designs, the additional space saved can be allocated to new components for added device functionality.

Amplifiers are commonly used in various electronic devices to provide signal amplification. Different types of amplifiers are available for different uses. For example, a wireless communication device such as a cellular phone may include a transmitter and a receiver for bi-directional communication.

CMOS power amplifiers (PAs) are becoming increasingly popular in a wide range of applications due to their advantages of low cost, small size, and high efficiency. Quad Flat No-Lead (QFN) packages are a popular choice for packaging CMOS PAs due to their low profile, small footprint, and good thermal performance. However, there are some challenges that must be considered when using QFN packages for CMOS PAs, such as grounding. In conventional leadframe semiconductor packages, the down bond is used to electrically connect the chip ground pad to the ground bar of the leadframe. The down bond contributes to the high-frequency gain drop due to source de-generation, which cannot be compensated by high-voltage MOS (HVMOS).

### SUMMARY

It is one object of the present disclosure to provide an improved semiconductor package in order to solve the deficiencies or shortcomings of the prior art.

One aspect of the present disclosure provides a semiconductor package including a leadframe comprising a die pad and a plurality of lead terminals disposed along a perimeter of the die pad; an integrated circuit (IC) die mounted on the die pad, the IC die comprising an active front surface and a passive rear surface opposite to the active front surface, wherein a plurality of input/output (I/O) pads is disposed on the active front surface, wherein the IC die comprises a semiconductor substrate, at least one circuit block fabricated on the semiconductor substrate, and at least one through substrate via (TSV) extending beyond the passive rear surface and extending through a thickness of the semiconductor substrate; a plurality of bond wires extending between the plurality of I/O pads and the plurality of lead terminals, respectively; and a molding compound encapsulating the IC die, the bond wires, and the leadframe.

According to some embodiments, the at least one circuit block is a part of a CMOS power amplifier.

According to some embodiments, the IC die is mounted on the die pad by using a conductive adhesive layer.

According to some embodiments, the at least one TSV comprises a protruding tip extending into the conductive adhesive layer, and wherein the at least one circuit block is electrically connected to the die pad through the at least one TSV.

According to some embodiments, the conductive adhesive layer comprises anisotropic conductive film, silver paste, or conductive die attach film.

According to some embodiments, the at least one TSV comprises a conductive core layer and a liner layer around the conductive core layer.

According to some embodiments, the passive rear surface and the protruding tip is covered with a back-side metal layer.

According to some embodiments, a bottom surface of the die pad is exposed from the molding compound.

According to some embodiments, the IC die is a WiFi chip.

According to some embodiments, the plurality of bond wires comprises gold wires or copper wires.

Another aspect of the present disclosure provides a method for forming a semiconductor package. A leadframe comprising a die pad and a plurality of lead terminals disposed along a perimeter of the die pad is provided. An integrated circuit (IC) die is mounted onto the die pad. The IC die includes an active front surface and a passive rear surface opposite to the active front surface. A plurality of input/output (I/O) pads is disposed on the active front surface. The IC die includes a semiconductor substrate, at least one circuit block fabricated on the semiconductor substrate, and at least one through substrate via (TSV) extending beyond the passive rear surface and extending through a thickness of the semiconductor substrate. A plurality of bond wires extends between the plurality of I/O pads and the plurality of lead terminals, respectively. A molding compound is formed to encapsulate the IC die, the bond wires, and the leadframe.

According to some embodiments, the at least one circuit block is a part of a CMOS power amplifier.

According to some embodiments, the IC die is mounted on the die pad by using a conductive adhesive layer.

According to some embodiments, the at least one TSV comprises a protruding tip extending into the conductive adhesive layer, and wherein the at least one circuit block is electrically connected to the die pad through the at least one TSV.

According to some embodiments, the conductive adhesive layer comprises anisotropic conductive film, silver paste, or conductive die attach film.

According to some embodiments, the at least one TSV comprises a conductive core layer and a liner layer around the conductive core layer.

According to some embodiments, the passive rear surface and the protruding tip is covered with a back-side metal layer.

According to some embodiments, a bottom surface of the die pad is exposed from the molding compound.

According to some embodiments, the IC die is a WiFi chip.

According to some embodiments, the plurality of bond wires comprises gold wires or copper wires.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a cross-sectional diagram showing a semiconductor package according to an embodiment of the present disclosure;

FIG. 2 to FIG. 4 illustrates an exemplary method for forming a semiconductor package according to an embodiment of the present disclosure; and

FIG. 5 is a cross-sectional diagram showing a semiconductor package according to another embodiment of the present disclosure.

### DETAILED DESCRIPTION

In the following detailed description of embodiments of the invention, reference is made to the accompanying drawings, which form a part hereof, and in which is shown by way of illustration specific preferred embodiments in which the disclosure may be practiced.

These embodiments are described in sufficient detail to enable those skilled in the art to practice them, and it is to be understood that other embodiments may be utilized and that mechanical, chemical, electrical, and procedural changes may be made without departing from the spirit and scope of the present disclosure. The following detailed description is, therefore, not to be taken in a limiting sense, and the scope of embodiments of the present invention is defined only by the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items. The term “dummy die”, which is a non-function die, is referred to as a semiconductor die or chip that does not have any electrical function.

High output power and good efficiency are important design goals for a power amplifier. A power amplifier may be required to transmit at a high maximum output power level. The power amplifier may be used in a wireless device and may consume a relatively large portion of the total power of the wireless device. Therefore, a power amplifier with high efficiency and high output power is desirable. One embodiment of the present disclosure pertains to a CMOS PA QFN package that is capable of enhancing the transmitter output power (TX Pout) by 0.7 dBm (per chain; simulated at the same power consumption level) and can achieve a relatively smaller form factor.

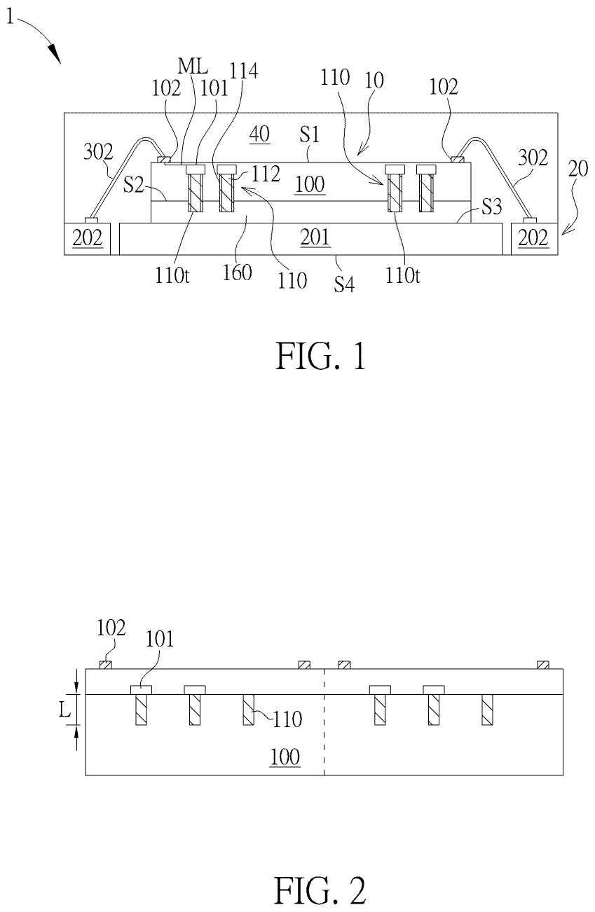

FIG. 1 is a cross-sectional diagram showing a semiconductor package according to an embodiment of the present disclosure. As shown in FIG. 1, the semiconductor package 1 comprises an integrated circuit (IC) die 10 such as a WiFi chip mounted on a die pad 201 of a leadframe 20 by using an adhesive layer 160. According to an embodiment of the present disclosure, the adhesive layer 160 may be a conductive adhesive film including, but not limited to, a silver paste or an anisotropic conductive film (ACF). According to an embodiment of the present disclosure, the IC die 10 comprises an active front surface S1 and a passive rear surface S2 that is opposite to the active front surface S1. A plurality of input/output (I/O) pads 102 may be disposed on the active front surface S1.

According to an embodiment of the present disclosure, the I/O pads 102 may be electrically connected to corresponding lead terminals 202 disposed along the perimeter of the die pad 201 via bond wires 302 such as gold wires or copper wires, but not limited thereto. It is to be understood that the semiconductor package 1 may be a multi-row QFN package although only one row of lead terminals 202 is shown.

According to an embodiment of the present disclosure, the die pad 201 comprises a top surface S3 and a bottom surface S4. The IC die 10 is mounted face up on the top surface S3 of the die pad 201 through the adhesive layer 160. A molding compound 40 such as an epoxy resin is provided to encapsulate the IC die 10, the bond wires 302, and the leadframe 20. According to an embodiment of the present disclosure, the bottom surface S4 may be exposed from the molding compound 40.

According to an embodiment of the present disclosure, the IC die 10 may comprise a semiconductor substrate 100 such as a silicon substrate, but not limited thereto. A plurality of circuit blocks 101 are fabricated on or in the semiconductor substrate 100 by using a front-end of line (FEOL) process. The FEOL process is the first major stage in semiconductor fabrication. The individual building blocks of an integrated circuit, like transistors, capacitors, and resistors, are formed directly on the semiconductor substrate 100. According to an embodiment of the present disclosure, for example, the circuit blocks 101 may be parts of a CMOS power amplifier, but not limited thereto.

According to an embodiment of the present disclosure, the IC die 10 may further comprise metal interconnect structures ML formed by using a back-end of line (BEOL) process. For example, the metal interconnect structures ML may comprise metal line, contacts and vias formed in different inter-layer dielectric layers. For example, the metal interconnect structures ML may comprise copper, tungsten, titanium, titanium nitride or the like, but not limited thereto. The metal interconnect structures ML may electrically connect the circuit blocks 101 to the I/O pads 102, but not limited thereto.

According to an embodiment of the present disclosure, a plurality of through substrate vias (TSVs) 110 may be provided in the semiconductor substrate 100. The TSVs 110 extend through the thickness of the semiconductor substrate 100. According to an embodiment of the present disclosure, each of the TSVs 110 may comprise a conductive core layer 112 and a liner layer 114 around the conductive core layer 112. According to an embodiment of the present disclosure, for example, the conductive core layer 112 may comprise copper or copper alloys, but not limited thereto. According to an embodiment of the present disclosure, for example, the liner layer 114 may comprise titanium nitride, but not limited thereto. According to an embodiment of the present disclosure, each of the TSVs 110 may comprise a protruding tip 110t extending beyond the passive rear surface S2 and extending into the conductive adhesive layer 160.

The TSVs 110 provide electrical contact between the grounded die pad 201 and the circuit blocks 101, thereby shortening the grounding path for the ground signal transmitted between the grounded die pad 201 and the circuit blocks 101, which improves the source impedance and enhances the transmitter output power.

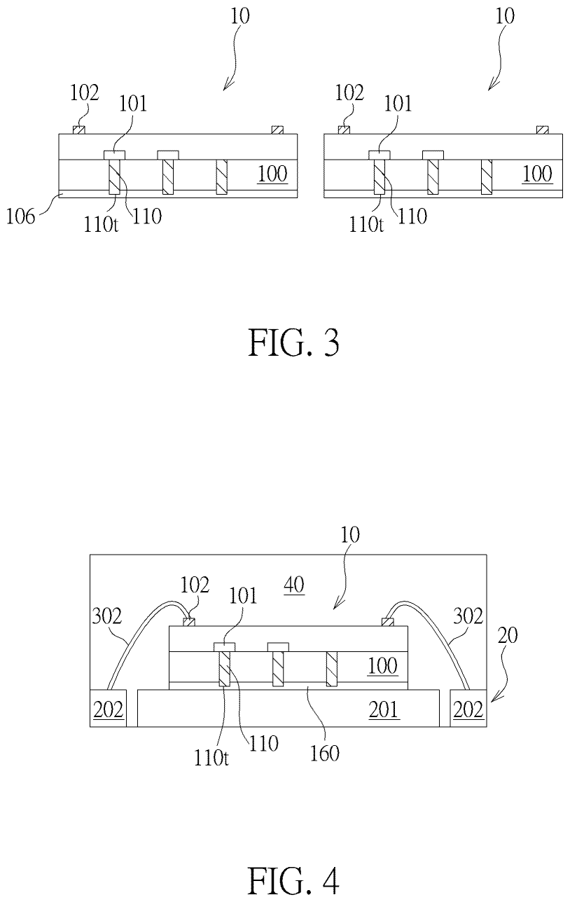

Please refer to FIG. 2 to FIG. 4, which illustrates an exemplary method for forming a semiconductor package according to an embodiment of the present disclosure, wherein like layers, regions or elements are designated by like numeral numbers or labels. As shown in FIG. 2, a semiconductor substrate 100 such as a P-type silicon wafer is provided. A plurality of circuit blocks 101 are fabricated on or in the semiconductor substrate 100 by using a front-end of line process. Each of the circuit blocks 101 may comprise transistors, capacitors, resistors, diodes, or diffusions, formed directly on the semiconductor substrate 100. According to an embodiment of the present disclosure, for example, the circuit blocks 101 may be parts of a CMOS power amplifier, but not limited thereto. According to an embodiment of the present disclosure, a plurality of through substrate vias (TSVs) 110 may be formed in the semiconductor substrate 100 by methods known in the art, for example, via-first TSV process. For example, the TSVs 110 may have a length L of about 60 micrometers. According to an embodiment of the present disclosure, an upper end of each of the TSVs 110 may be electrically connected to the corresponding one of the circuit blocks 101.

As shown in FIG. 3, the semiconductor substrate 100 is then subjected to a wafer backside grinding or polishing process to reduce the thickness of the semiconductor substrate 100 until the lower ends of the TSVs 110 are exposed. According to an embodiment of the present disclosure, as previously described, each of the TSVs 110 may comprise a conductive core layer and a liner layer around the conductive core layer. According to an embodiment of the present disclosure, each of the TSVs 110 may comprise a protruding tip 110t extending beyond the passive rear surface S2. Subsequently, an adhesive layer 160 such as ACF, silver paste, or a conductive die attach film is disposed on the polished bottom surface of the semiconductor substrate 100. The protruding tip 110t of each of the TSVs 110 may extend into the adhesive layer 160. A wafer dicing process may be performed to form individual IC dies 10. After dicing, the individual IC dies 10 may be carefully removed and singulated using specialized equipment. They are then inspected and sorted for further processing and packaging.

As shown in FIG. 4, the IC die 10 is then mounted onto a die pad 201 of a leadframe 20 via the adhesive layer 160. According to an embodiment of the present disclosure, the I/O pads 102 of the IC die 10 may be electrically connected to corresponding lead terminals 202 disposed along the perimeter of the die pad 201 via bond wires 302 such as gold wires or copper wires, but not limited thereto. A molding process is then performed to form a molding compound 40 that encapsulates the IC die 10, the bond wires 302, and the leadframe 20.

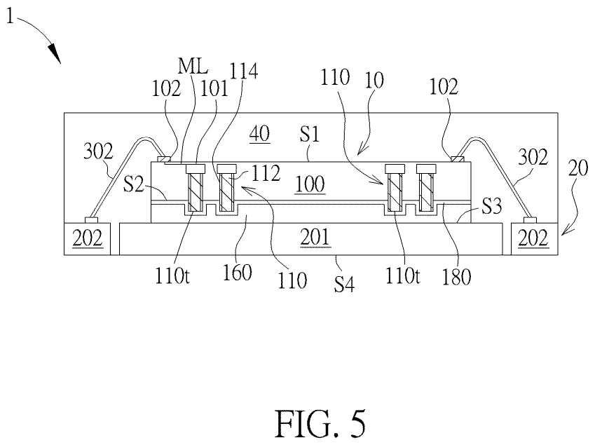

FIG. 5 is a cross-sectional diagram showing a semiconductor package according to another embodiment of the present disclosure. As shown in FIG. 5, after performing the wafer backside grinding or polishing process, a back-side metal layer 180 may be conformally deposited on the passive rear surface S2 and the protruding tip 110t of each of the TSVs 110. Subsequently, an adhesive layer 160 such as ACF, silver paste, or a conductive die attach film is disposed on the back-side metal layer 180. After singulation, the IC die 10 is then mounted onto a die pad 201 of a leadframe 20 via the adhesive layer 160. According to an embodiment of the present disclosure, the I/O pads 102 of the IC die 10 may be electrically connected to corresponding lead terminals 202 disposed along the perimeter of the die pad 201 via bond wires 302 such as gold wires or copper wires, but not limited thereto. A molding process is then performed to form a molding compound 40 that encapsulates the IC die 10, the bond wires 302, and the leadframe 20.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor package, comprising:
a leadframe comprising a die pad and a plurality of lead terminals disposed along a perimeter of the die pad;
an integrated circuit (IC) die mounted on the die pad, the IC die comprising an active front surface and a passive rear surface opposite to the active front surface, wherein a plurality of input/output (I/O) pads is disposed on the active front surface, wherein the IC die comprises a semiconductor substrate, at least one circuit block fabricated on the semiconductor substrate, and at least one through substrate via (TSV) extending beyond the passive rear surface and extending through a thickness of the semiconductor substrate;
a plurality of bond wires extending between the plurality of I/O pads and the plurality of lead terminals, respectively; and
a molding compound encapsulating the IC die, the bond wires, and the leadframe.

2. The semiconductor package according to claim 1, wherein the at least one circuit block is a part of a CMOS power amplifier.

3. The semiconductor package according to claim 2, wherein the IC die is mounted on the die pad by using a conductive adhesive layer.

4. The semiconductor package according to claim 3, wherein the at least one TSV comprises a protruding tip extending into the conductive adhesive layer, and wherein the at least one circuit block is electrically connected to the die pad through the at least one TSV.

5. The semiconductor package according to claim 3, wherein the conductive adhesive layer comprises anisotropic conductive film, silver paste, or conductive die attach film.

6. The semiconductor package according to claim 1, wherein the at least one TSV comprises a conductive core layer and a liner layer around the conductive core layer.

7. The semiconductor package according to claim 4, wherein the passive rear surface and the protruding tip is covered with a back-side metal layer.

8. The semiconductor package according to claim 1, wherein a bottom surface of the die pad is exposed from the molding compound.

9. The semiconductor package according to claim 1, wherein the IC die is a WiFi chip.

10. The semiconductor package according to claim 1, wherein the plurality of bond wires comprises gold wires or copper wires.

11. A method for forming a semiconductor package, comprising:
providing a leadframe comprising a die pad and a plurality of lead terminals disposed along a perimeter of the die pad;
mounting an integrated circuit (IC) die onto the die pad, the IC die comprising an active front surface and a passive rear surface opposite to the active front surface, wherein a plurality of input/output (I/O) pads is disposed on the active front surface, wherein the IC die comprises a semiconductor substrate, at least one circuit block fabricated on the semiconductor substrate, and at least one through substrate via (TSV) extending beyond the passive rear surface and extending through a thickness of the semiconductor substrate;
forming a plurality of bond wires extending between the plurality of I/O pads and the plurality of lead terminals, respectively; and
forming a molding compound to encapsulate the IC die, the bond wires, and the leadframe.

12. The method according to claim 11, wherein the at least one circuit block is a part of a CMOS power amplifier.

13. The method according to claim 12, wherein the IC die is mounted on the die pad by using a conductive adhesive layer.

14. The method according to claim 13, wherein the at least one TSV comprises a protruding tip extending into the conductive adhesive layer, and wherein the at least one circuit block is electrically connected to the die pad through the at least one TSV.

15. The method according to claim 13, wherein the conductive adhesive layer comprises anisotropic conductive film, silver paste, or conductive die attach film.

16. The method according to claim 11, wherein the at least one TSV comprises a conductive core layer and a liner layer around the conductive core layer.

17. The method according to claim 14, wherein the passive rear surface and the protruding tip is covered with a back-side metal layer.

18. The method according to claim 11, wherein a bottom surface of the die pad is exposed from the molding compound.

19. The method according to claim 11, wherein the IC die is a WiFi chip.

20. The method according to claim 11, wherein the plurality of bond wires comprises gold wires or copper wires.
